(19) United States
(12) Patent Application Publication
(10) Pub. No.: US 2004/0169539 A1
(43) Pub. Date: Sep. 2, 2004

(54) Miller effect compensation technique for DLL phase interpolator design

(76) Inventors: Claude R. Gauthier, Cupertino, CA (US); Brian W. Amick, Austin, TX (US); Dean Liu, Sunnyvale, CA (US)

Correspondence Address: OSHA & MAY L.L.P./SUN, 1221 MCKINNEY, SUITE 2800, HOUSTON, TX, 77010, US

(21) Appl. No.: 10/377,427

(22) Filed: Feb. 28, 2003

(51) Int. Cl. H03K 3/00

(52) U.S. Cl. 327/231

(57) ABSTRACT

A delay locked loop design uses a fixed capacitance to load down a signal output from a phase selector of the delay locked loop to a phase interpolator of the delay locked loop. Such loading counteracts for variable capacitive coupling that occurs in the phase interpolator as interpolation weights to the phase interpolator change. Without such loading of the output of the phase selector, the delay of the phase selector varies as a function of the capacitance coupling of the phase interpolator.

### BACKGROUND OF INVENTION

As the frequencies of modern computers continue to increase, the need to rapidly transmit data between chip interfaces also increases. To accurately receive data, a clock is often sent to help recover the data. The clock determines when the data should be sampled by a receiver's circuits.

The clock may transition at the beginning of the time the data is valid. The receiver would prefer, however, to have a signal during the middle of the time the data is valid. Also, the transmission of the clock may degrade as it travels from its transmission point. In both circumstances, a delay locked loop, or DLL, can regenerate a copy of the clock signal at a fixed phase shift from the original.

FIG. 1 shows a section of a typical computer system component 10. Data 22 that is ‘n’ bits wide is transmitted from circuit A 20 to circuit B 40. To aid in the recovery of the transmitted data, a clock composed of a clock signal 30, or CLK, is also transmitted with the data. The circuits could also have a path to transmit data from circuit B 40 to circuit A 20 along with an additional clock (not shown).

The clock signal 30 may transition from one state to another at the beginning of the data transmission. Circuit B 40 requires a signal temporally located some time after the beginning of the valid data. Furthermore, the clock signal 30 may have degraded during transmission. A DLL has the ability to regenerate the clock signal 30 to a valid state and to create a phase shifted version of the clock to be used by other circuits, for example, a receiver's sampling signal.

The receiver's sampling signal determines when the input to the receiver should be sampled.

The DLL must delay an output signal versus an input signal by a known phase shift. The entire cycle of a signal is considered a 360 degree phase shift. By specifying a phase shift delay, the same relative delay is specified; however, the absolute amount of delay may be different. For example, a 100 MHz clock signal has a 10 ns cycle time. Therefore, a phase shift of 360 degrees would indicate that an entire cycle, or 10 ns, of delay has been added. A 30 degree phase shift is approximately 0.833 ns. A 200 MHz clock signal has a cycle time of 5 ns. A 30 degree phase shift is approximately 0.417 ns. The phase shifts in these examples are the same; however, the temporal delays are not.

In FIG. 2, a DLL 50 is composed of three basic components: a delay element 52, a buffer circuit 54, and a phase detector and delay control 60. The delay element 52 generates a delayed signal 53 that is delayed relative an input signal 30. For this example, the input signal 30 is CLK. The phase detector and delay control 60, or phase adjustment device, controls the amount of delay generated by the delay element 52 based on the phase difference between the input signal 30 and a buffered output signal 55. The buffer circuit 54 takes the delayed signal 53 from the delay element 52 and buffers the delayed signal 53 to any circuits that must receive a buffered output signal 55, such as a receiver's sampling signal. By buffering the output signal 53, the characteristics of the delay element 52 are not changed due to the capacitive and/or resistive load on the delayed signal 53.

### SUMMARY OF INVENTION

According to one or more embodiments of the present invention, an integrated circuit comprises a phase selector stage arranged to receive phase shifted signals and output at least a pair of the phase shifted signals, at least one signal wire arranged to propagate the at least a pair of the phase shifted signals, a phase interpolator stage having an input operatively connected to the at least one signal wire (where the phase interpolator stage is arranged to receive the at least a pair of the phase shifted signals and interpolate between the at least a pair of the phase shifted signals), and at least one capacitor operatively connected to the at least one signal wire.

According to one or more embodiments of the present invention, an integrated circuit comprises means for generating phase shifted signals dependent on an input clock signal, means for selecting at least a pair of the phase shifted signals, means for propagating the selected at least a pair of the phase shifted signals, means for interpolating between the selected at least a pair of the phase shifted signals, and means for loading the means for propagating such that the means for interpolating does not substantially load the means for selecting.

According to one or more embodiments of the present invention, a method for operating a delay locked loop comprises inputting a plurality of phase shifted differential signal pairs, selecting at least one of the phase shifted differential signal pairs, propagating the at least one selected phase shifted differential signal pair, interpolating between signals in the at least one selected phase shifted differential signal pair, and capacitively loading the propagating such that the interpolating does not substantially affect the selecting.

Other aspects and advantages of the invention will be apparent from the following description and the appended claims.

### BRIEF DESCRIPTION OF DRAWINGS

FIG. 1 shows a typical computer system component.

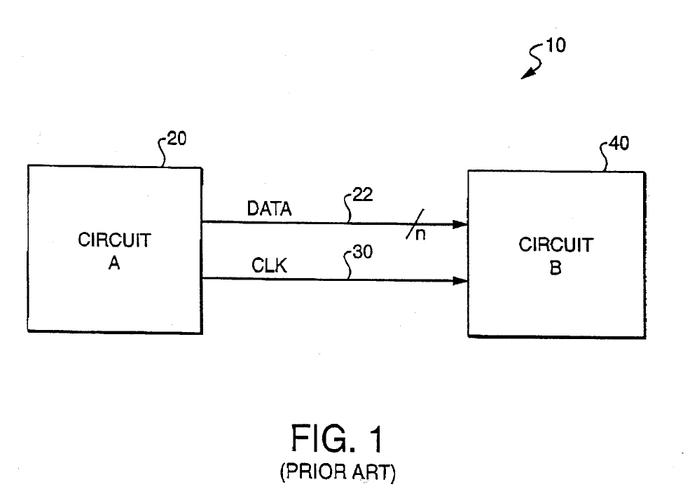

FIG. 2 shows a delay locked loop block diagram.

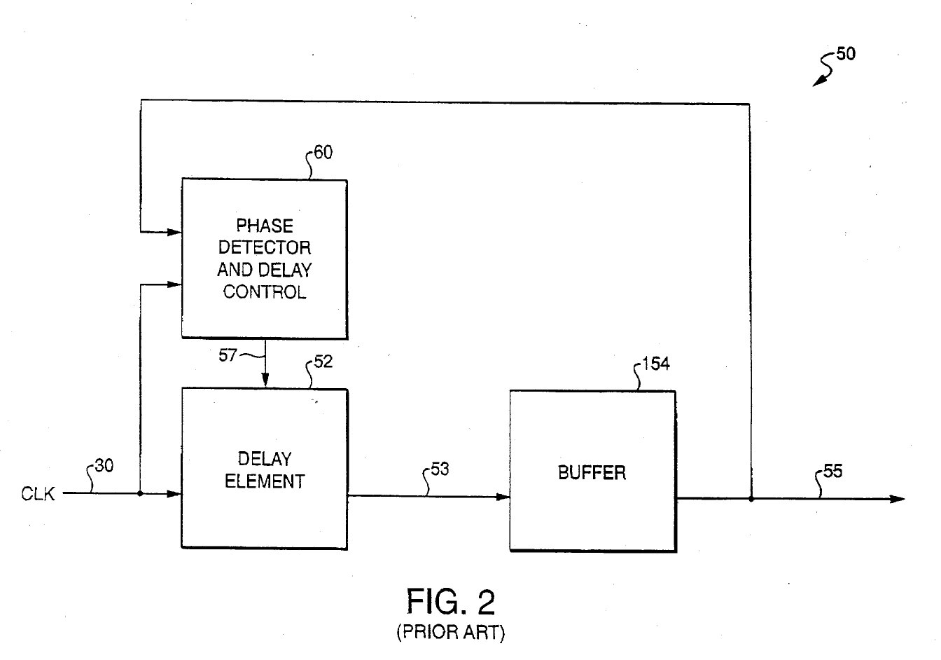

FIG. 3 shows a block diagram of a typical delay locked loop.

FIG. 4 shows a portion of a delay locked loop.

FIG. 5 shows a behavioral graph relating to the portion of the delay locked loop shown in FIG. 4.

FIG. 6 shows a portion of a delay locked loop in accordance with an embodiment of the present invention.

FIG. 7 shows a behavioral graph relating to the portion of the delay locked loop shown in FIG. 6.

### DETAILED DESCRIPTION

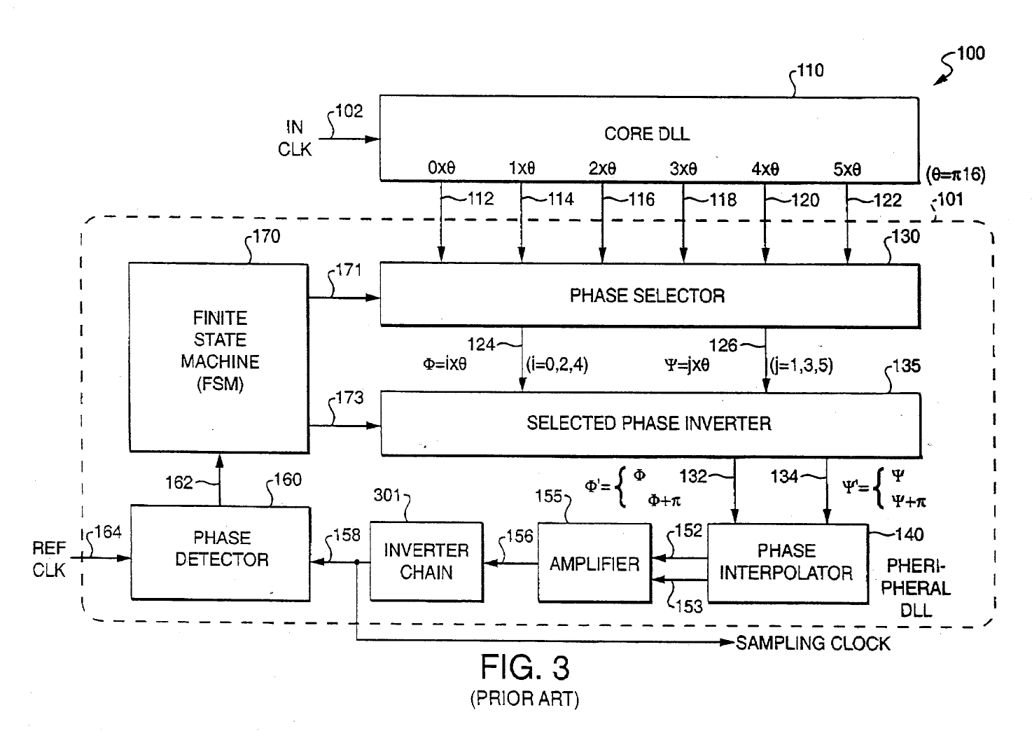

FIG. 3 shows a block diagram 100 of a delay locked loop (DLL) architecture. This architecture is based on two cascaded loops: a conventional first-order analog core DLL 110 and a digital peripheral DLL 101. The core DLL 110 is locked at a 180 degrees phase shift. Assuming that the delay line of the core DLL 110 comprises six buffers, their outputs are six clocks having phases evenly spaced by 30 degrees. The core DLL 110 has an input of IN CLK 102 that is used to create the six delayed outputs. The first output is a zero degree phased output 112 with each subsequent output adding an additional 30 degree phase shift at phased outputs 114, 116, 118, 120, and 122, respectively.

The peripheral DLL 101 selects a pair of clocks, φ 124 and ψ 126, to interpolate between. The clocks, φ 124 and ψ 126, are selected from the six phased outputs 112, 114, 116, 118, 120, and 122 by a phase selector 130. Clocks φ 124 and ψ 126 can potentially be inverted in order to cover the full 0 degree to 360 degree phase range by a selective phase inverter 135. Clocks φ′ 132 and ψ′ 134 drive a digitally controlled phase interpolator 140 which generates a differential clock: main clock Θ 152 and its complement, main clock Θ_153. The phase of the main clock Θ 152 (and its complement) can be any of the N quantized phase steps between the phases of clocks φ′ 132 and ψ′ 134, where O . . . N is the interpolation controlling word range. The main clock Θ 152 is approximately equal to φ′+(1−α/16)×(ψ′−φ′) where α=(0, 1, . . . , 16).

The main clock Θ 152 and main clock Θ_153 of the phase interpolator 140 drive an amplifier 155 that increases a voltage swing of the main clock Θ 152 and main clock Θ_153 to create a larger relative voltage swing at the amplifier output 156. The amplifier output 156 characteristics may follow the main clock Θ 152 characteristics with the larger relative voltage swing. The inverter chain 301 buffers the amplifier output 156. A buffer, for the purposes of this description, creates a copy of the input signal at the output that is better suited to drive a larger load (i.e., generates a rise or fall time of the output signal similar to the input signal even though the amount of resistance and/or capacitance attached to the output is greater). The inverter chain 301 buffers the amplifier output 156 and generates an inverter chain output 158 to drive a sampling clock (i.e., latching signal) of one or more receivers.

The inverter chain output 158 also drives a phase detector 160 that compares the inverter chain output 158 to a reference clock, REF CLK, 164. A phase detector output 162 is used by a finite state machine (FSM) 170 to control the phase selector 130 and the selective phase inverter 135, through FSM control lines 171 and 173, respectively. The finite state machine (FSM) 170 also controls the phase interpolator 140 mixing weight (not shown).

The FSM 170 adjusts the phase of the main clock Θ 152 and main clock Θ_153 according to the phase detector output 162. Generally, this means just changing the phase interpolator 140 mixing weight by one. If, however, the phase interpolator 140 controlling word has reached its minimum or maximum limit, the FSM 170 must change the phase of φ 124 or ψ 126 to the next appropriate selection. This phase selection change might also involve an inversion of the corresponding clock if the current interpolation interval is adjacent to the 0 degree or 180 degree boundary. As these phase selection changes happen only when the corresponding phase mixing weight is zero, no glitches occur on the output clock. The digital “bang-bang” nature of the control results in dithering around the zero phase error point in the lock condition. The dither amplitude is determined by the phase interpolator 140 and the delay through the peripheral DLL 101.

In this architecture, the main clock Θ 152 and main clock Θ_153 phase can be rotated, so no hard limits exist in the loop phase capture range: the loop provides unlimited (modulo 2π) phase shift capability. This property eliminates boundary conditions and phase relationship constraints. The only requirement is that the IN CLK 102 and REF CLK 164 are plesiochronous (i.e., their frequency difference is bounded), making this architecture suitable for clock recovery applications.

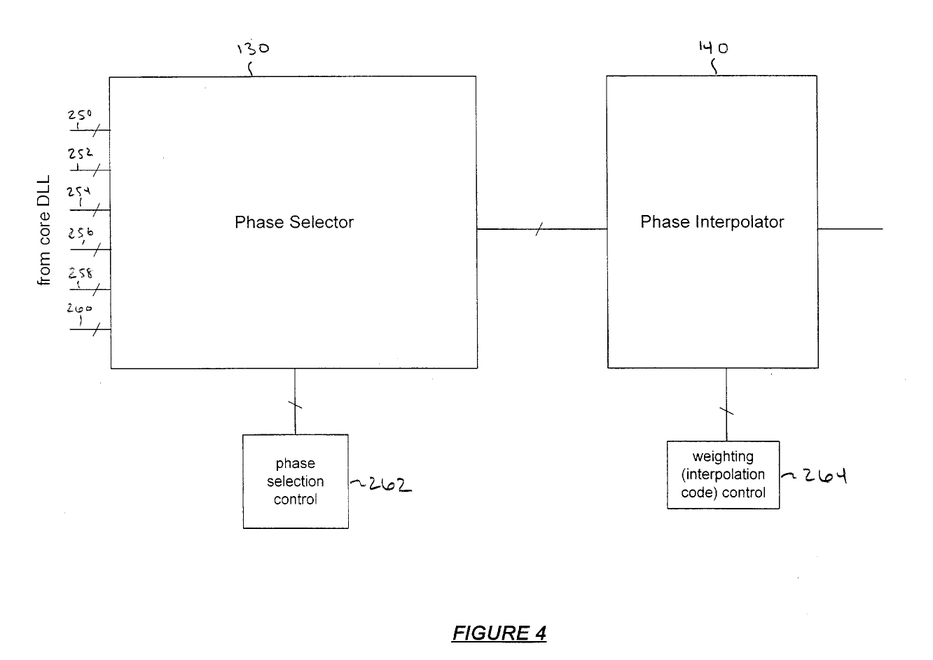

FIG. 4 shows a logic level diagram of a portion of the delay locked loop 101 shown in FIG. 3 involving the phase selector stage 130 and the phase interpolator stage 140. The phase selector stage 130 inputs six pairs of phase shifted differential signals 250, 252, 254, 256, 258, and 260 from the DLL core (110 in FIG. 3). Depending on some phase selection control logic 262, one of the six pairs of phase shifted differential signals 250, 252, 254, 256, 258, and 260 is selected and outputted to the phase interpolator stage 140, which, in turn, interpolates between the selected phase shifted differential signal pair dependent on weighting, or interpolation code, control logic 264.

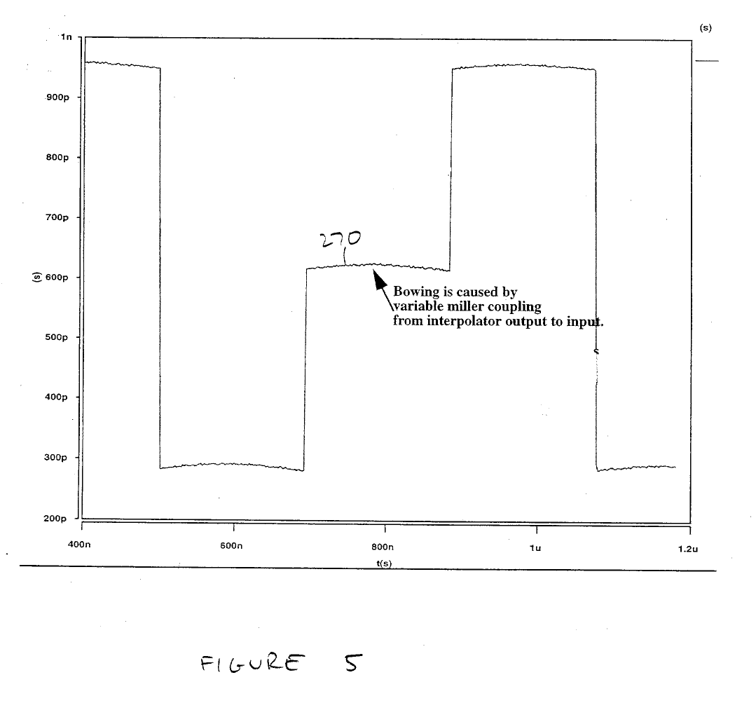

To demonstrate one behavioral aspect of the portion of the delay locked loop shown in FIG. 4, FIG. 5 shows a graph of the delay of the phase selector stage 130 as the interpolation codes, i.e., weights, to the phase interpolator stage 140 change. As can be seen in FIG. 5, there is a “bowing” 270 in this delay of the phase selector stage 130. Those skilled in the art will understand that this “bowing” effect peaks when the interpolation weight to the phase interpolator stage 140 is 50%. This results from the fact that the input capacitance to the phase interpolator stage 140 is actually variable dependent on the interpolation codes, i.e., weights applied to the phase interpolator stage 140. Thus, the phase interpolator stage 140 can be viewed as substantially loading the phase selector stage 130. In other words, the capacitive coupling from the input of the phase interpolator stage 140 to the output of the phase interpolator stage 140 varies as the output waveform from the phase interpolator stage 140 changes. Such an effect is known as a “Miller” effect. Accordingly, such indeterministic capacitive coupling in the phase interpolator stage 140 causes variance in the delay of the phase selector stage 130.

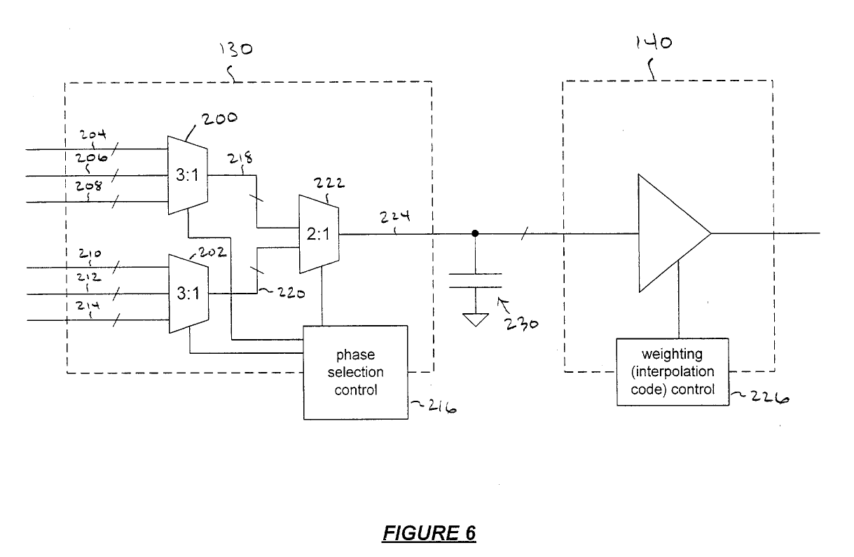

In order to counteract such a Miller effect, embodiments of the present invention relate to a delay locked loop design that compensates for the variable capacitive coupling in a phase interpolator stage of the delay locked loop. FIG. 6 shows a portion of a delay locked loop in accordance with an embodiment of the present invention. In part, FIG. 6 shows the phase selector stage 130 and the phase interpolator stage 140. The phase selector stage 130 includes two 3:1 multiplexors 200 and 202 that each select one of three phase shifted differential signal pairs 204, 206, 208, 210, 212, and 214 depending on phase selection control logic 216. The outputs 218 and 220 from the two 3:1 multiplexors 200 and 202 serve as inputs to a 2:1 multiplexor 222, which, in turn, outputs a selected phase shifted differential signal pair 224 dependent on the phase selection control logic 216. The selected differential signal pair 224 is transmitted to the phase interpolator stage 140 for interpolation, where the interpolation is dependent on weighting, or interpolation code, control logic 226.

In order to compensate for the variable capacitive loading on the phase selector stage 130 by the phase interpolator stage 140 that occurs as the interpolation codes to the phase interpolator 140 change, a fixed capacitance is operatively connected to the signal wire 224 connecting the phase selector stage 130 and the phase interpolator stage 140. Such a fixed capacitance may be chosen so as to dominate the variability of capacitive coupling in the phase interpolator stage 140. In effect, the signal wire 224 is “loaded down” by the fixed capacitance 230 so as to not be substantially affected by the changing capacitive coupling in the phase interpolator stage 140. Those skilled in the art will understand that the fixed capacitance 230 shown in FIG. 6 may be implemented by a variety of means, e.g., metal capacitors, off-chip capacitors, gate capacitors, etc.

Those skilled in the art will further understand that, in one or more embodiments, the multiplexors in a phase selector stage of a delay locked loop may be sized to effectuate desired edge rates on signals generated from the phase selector stage. Moreover, those skilled in the art will understand that, in one or more embodiments, the phase selector stage may be designed so as to contain any number of multiplexors.

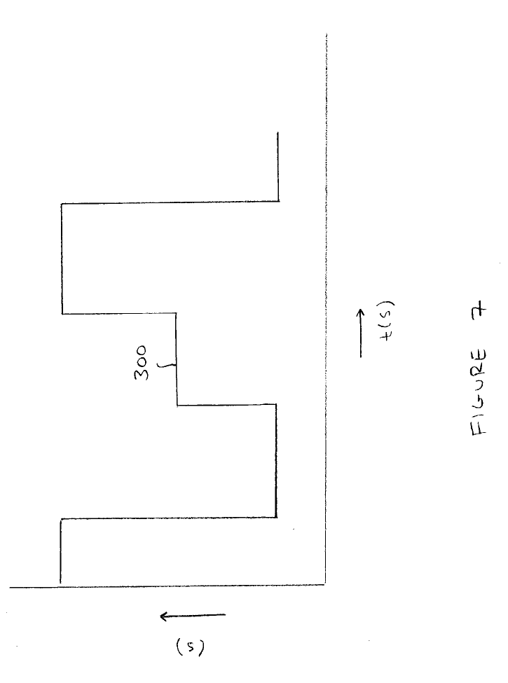

To demonstrate one behavioral aspect of the portion of the delay locked loop shown in FIG. 6, FIG. 7 shows a graph of the delay of the phase selector stage 130 as the interpolation codes, i.e., weights, to the phase interpolator stage 140 change. As can be seen in FIG. 7 with reference to FIG. 5, a “bowing” 300 in FIG. 7 is flattened with respect to the “bowing” (270 in FIG. 5) shown in FIG. 5. This flattening results from the loading down, by means of the fixed capacitance 230, of the signal wire (224 in FIG. 6) operatively connecting the phase selector stage (130 in FIG. 6) and the phase interpolator stage (140 in FIG. 6).

Advantages of the present invention may include one or more of the following. In one or more embodiments, because a delay locked loop is designed to compensate for variable capacitive coupling present in a phase interpolator of the delay locked loop, a delay through a phase selector of the delay locked loop may remain constant.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. An integrated circuit, comprising:
a phase selector stage arranged to receive phase shifted signals and output at least a pair of the phase shifted signals;
at least one signal wire arranged to propagate the at least a pair of the phase shifted signals;
a phase interpolator stage having an input operatively connected to the at least one signal wire, wherein the phase interpolator stage is arranged to receive the at least a pair of the phase shifted signals and interpolate between the at least a pair of the phase shifted signals; and
at least one capacitor operatively connected to the at least one signal wire.

2. The integrated circuit of claim 1, wherein the at least one capacitor has a capacitance that loads down the at least one signal wire such that the phase interpolator stage cannot substantially load the phase selector stage.

3. The integrated circuit of claim 1, further comprising a finite state machine, wherein the phase selector stage is dependent on the finite state machine, and wherein the finite state machine is dependent on the phase interpolator stage.

4. The integrated circuit of claim 1, further comprising a phase selection control logic, wherein the phase selector stage is dependent on the phase selection control logic.

5. The integrated circuit of claim 4, the phase selector stage comprising:
at least one multiplexor arranged to input at least one of the phase shifted signals and output a selected phase shifted signal dependent on the phase selection control logic.

6. The integrated circuit of claim 1, further comprising interpolation code control logic, wherein the phase interpolator stage is dependent on the interpolation code control logic.

7. The integrated circuit of claim 1, further comprising a delay locked loop that comprises the phase selector stage and the phase interpolator stage.

8. The integrated circuit of claim 1, wherein a coupling capacitance of the phase interpolator stage varies as interpolation codes to the phase interpolator stage vary.

9. The integrated circuit of claim 1, wherein the phase selector stage is arranged to receive phase shifted signal from a core delay locked loop.

10. The integrated circuit of claim 9, wherein the phase shifter signals are generated dependent on an input clock signal to the core delay locked loop.

11. The integrated circuit of claim 1, wherein the at least one capacitor is a metal capacitor.

12. The integrated circuit of claim 1, wherein the at least one capacitor is one of a gate capacitor and an off-chip capacitor.

13. An integrated circuit, comprising:
means for generating phase shifted signals dependent on an input clock signal;
means for selecting at least a pair of the phase shifted signals;
means for propagating the selected at least a pair of the phase shifted signals;
means for interpolating between the selected at least a pair of the phase shifted signals; and
means for loading the means for propagating such that the means for interpolating does not substantially load the means for selecting.

14. The integrated circuit of claim 13, further comprising a means for controlling the means for selecting.

15. The integrated circuit of claim 14, wherein the means for controlling is dependent on the means for interpolating.

16. The integrated circuit of claim 14, wherein the means for selecting comprises means for inputting the phase shifted signals and means for outputting the at least a pair of the phase shifted signals dependent on the means for controlling.

17. A method for operating a delay locked loop, comprising:
inputting a plurality of phase shifted differential signal pairs;
selecting at least one of the phase shifted differential signal pairs;
propagating the at least one selected phase shifted differential signal pair;
interpolating between signals in the at least one selected phase shifted differential signal pair; and
capacitively loading the propagating such that the interpolating does not substantially affect the selecting.

18. The method of claim 17, further comprising generating the plurality of phase shifted differential signal pairs dependent on a clock signal.

19. The method of claim 17, further comprising controlling the selecting, wherein the controlling is dependent on the interpolating.

20. The method of claim 17, generating a sampling clock signal dependent on the interpolating.
